(19) United States
(12) Patent Application Publication
(10) Pub. No.: US 2007/0096714 A1
(43) Pub. Date: May 3, 2007

(54) Electricians phase tester

(75) Inventor: Philip Joseph Catalano, Orlando, FL (US)

Correspondence Address: Philip Joseph Catalano, 1420 Francis Avenue, Orlando, FL, 32806-2448, US

(73) Assignee: Philip Joseph Catalano, Orlando, FL (US)

(21) Appl. No.: 11/515,269

(22) Filed: Sep. 1, 2006

Related U.S. Application Data
(60) Provisional application No. 60/731,699, filed on Oct. 31, 2005.

(51) Int. Cl. G01R 23/12; G01R 25/00

(52) U.S. Cl. 324/76.52; 324/86

(57) ABSTRACT

My invention described is an electronic phase tester used to identify unmarked large feeder conductors to color code for phase orientation. This new process eliminates the manual labor required to ohm meter test each conductor to opposite conductor one at a time, a continuity test. To save labor and time this new way also eliminates the power on phase rotation test, as the electrician must work with power on to perform this test with the phase tester now known. This test is a shock hazard to the electrician in the field today. With the use of four LED's and a circuit to indicate each phase with power off and a one time test all phase orientation is completed in a one step process. And a single person performs the test. This is a safe way to test rotation and a new way to save time to color code and tape power feeders to give correct phasing, ABCN, of multi-phase power source on all three phases at one time.

### BACKGROUND OF THE INVENTION

This invention relates to an electronic circuit to test correct phase orientation of a multi phase source.

Over the years electricians have used colored phase tape applied to feeder conductors before conductors are pulled into a raceway. This has been a problem as phase tape cannot be applied on the opposite end. On twisted multi paralled feeders on the opposite end do to rolled end of the conductors this end is located inside the spool and covered with loops on top of loops maybe hundered of wraps of many loops. Impossible to locate the ends of conductors. Only the pull side can be color coded.

Another drawback is tape applied to the wrong phase or conductor, human error of personnel is common so they must ohm meter test after a pull is made to check phasing. A continuity check.

One of the most formidable problems is the power turn on test A phase meter is connected to ABC on a hot feeder. This is a major safety hazard, it exposes the electrician to a potential shock hazard, as the connection is made hot If any phase is connected to ground or neutral a shock or explosion may be fatal. This has been done for many years and is a very common test in the field.

This method of testing is unsafe and time lost in labor, hence we need a new way. An accurate and safe way to test phase rotation of feeders and conductors. A reliable one time test for electricians. My invention is to provide a new way that will avoid these problems.

### BRIEF SUMMARY OF THE INVENTION

It is therefore the objective of this invention to provide an improved way of testing phase rotation and orientation of multi phase power feeders.

It is a further objective of this invention to make a safe work environment for electricians in the field exposed to electrical shock hazards.

It is a further objective of this invention to save time and labor costs by testing all phases at one time and saving on phase tape applied many times, which eliminates human error.

The invention results from the realization that a simple circuit and LED's can make the work place safe and cost effective, to do a test and no other labor or work is required.

### BRIEF DESCRIPTION OF DRAWINGS

Other objects, features and advantages will occur to those skilled in the art from the following description of a preferred embodiment and accompanying drawings.

FIG. 1, Page 8 is an overall view of the process and function of said invention.

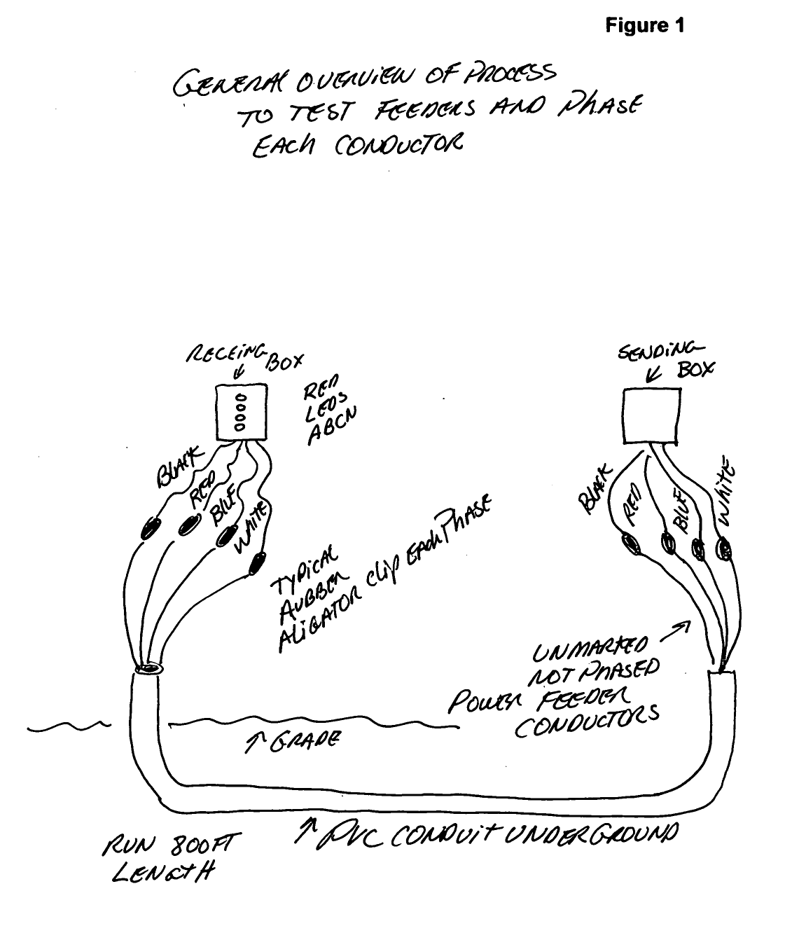

FIG. 2, Page 9 is schematic of sending and receiving circuits, phase test leads, connections.

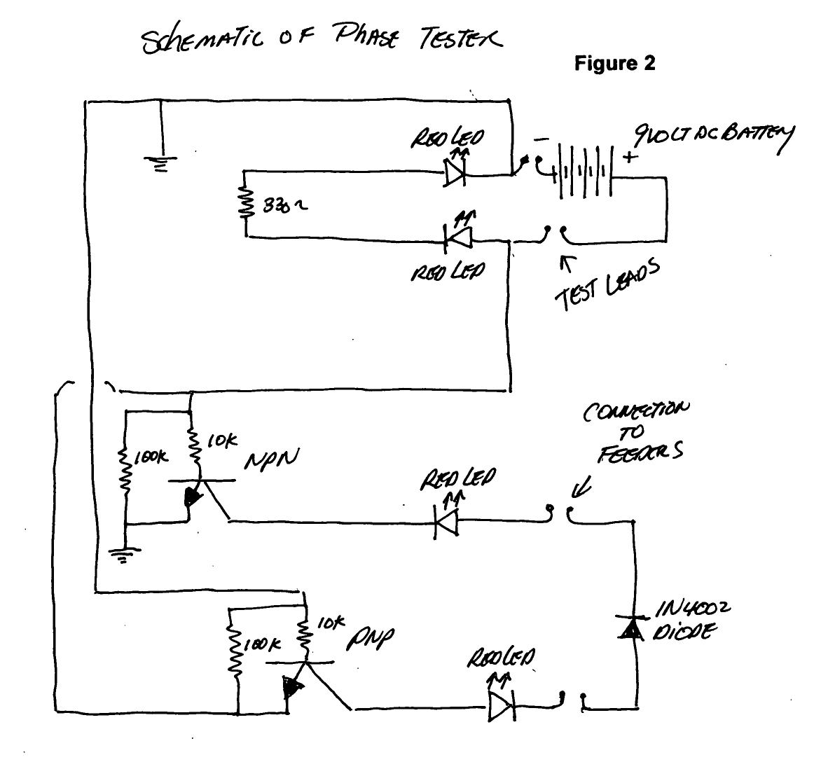

FIG. 3, Page 10 is tester boxes, sending box, receiving box and test leads. Also shown ABCN LED's on receiving box upper case cover.

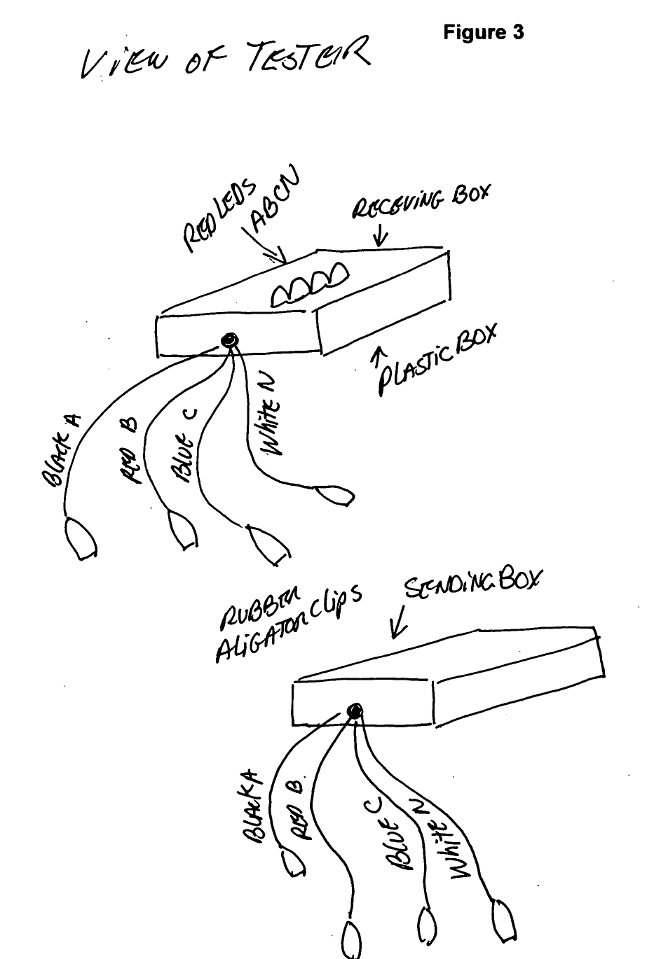

### DETAILED DESCRIPTION OF THE INVENTION

The first event in sequence of the process of phase test is to attach the sending leads—A black—B red—C blue—N white, to four conductors on any side of raceway or conduit These conductors are black at this time, then to color code each conductor to match the colors of the test lead's and apply colored phase tape to match.

The next step is to attach the receiving leads to the opposite feeder ends opposite end of the run of conduit or raceway. They will turn on only in the proper order A B first C N last, and only illuminate LED's in the correct match of the sending circuit box. At this time the phase color tape is placed on each conductor which now matches opposite end of the run of the feeder or conductor under test. Rotation and orientation is now finished and ready for termination to lugs or breakers of high voltage switch board. The test is completed.

What I claim as my invention is:

1. A phase tester to give all orientation of phases in a one time test, a sending circuit and a receiving circuit to process each phase and to illuminate LED's on in correct order of rotation A-B-C-N.

2. A phase tester according to claim 1 wherein color coded leads and aligator clips extend to attach to power feeders for a connection to said sending circuit and said receiving circuit.
